(19) United States
(12) Patent Application Publication
(10) Pub. No.: US 2015/0090983 A1
(43) Pub. Date: Apr. 2, 2015

(54) DISPLAY UNIT AND ELECTRONIC APPARATUS

(71) Applicant: Sony Corporation, Tokyo (JP)

(72) Inventor: Nobuo Ozawa, Kanagawa (JP)

(73) Assignee: Sony Corporation, Tokyo (JP)

(21) Appl. No.: 14/493,546

(22) Filed: Sep. 23, 2014

(30) Foreign Application Priority Data
Sep. 30, 2013 (JP) 2013-203172

(51) Int. Cl. H01L 27/32; H01L 51/52

(52) U.S. Cl. CPC H01L 27/3276; H01L 51/5203; H01L 51/5237
USPC 257/40

(57) ABSTRACT

A display unit includes: a plurality of light emitting elements provided in a display region of a first substrate, and including a first electrode, a light emitting layer, and a second electrode in this order on the first substrate; an auxiliary wiring provided on a second substrate facing the first substrate with the light emitting elements interposed therebetween, and extending from the display region to a peripheral region surrounding the display region; a first pillar configured to electrically connect the auxiliary wiring and the second electrode of the light emitting elements; and a second pillar configured to electrically connect the auxiliary wiring and a peripheral electrode provided in the peripheral region of the first substrate.

### CROSS REFERENCE TO RELATED APPLICATIONS

This application claims the benefit of Japanese Priority Patent Application JP2013-203172 filed Sep. 30, 2013, the entire contents of which are incorporated herein by reference.

### BACKGROUND

The present technology relates to a display unit and an electronic apparatus that include a light emitting element such as an organic light emitting element.

In recent years, organic electroluminescence (EL) displays using a self-light-emitting-type organic light emitting element including an organic layer have been made practical. The organic EL displays are of the self-light-emitting type and therefore have wide viewing angle and sufficient responsivity to a high-definition high-speed video signal, as compared with liquid crystal displays.

For organic light emitting elements, it has been attempted to improve display performance by introducing a resonator structure, and controlling light generated in a light emitting layer by enhancing color purity of light emission color or increasing luminous efficiency. The organic light emitting elements may adopt, for example, a structure in which a first electrode, an organic layer, and a second electrode are laminated in this order on a first substrate, with a drive circuit including components such as a drive transistor interposed therebetween. In the organic light emitting elements, when being of a top-surface light emission type (a top emission method), the second electrode is configured of a transparent conductive material, light from the organic layer is multi-reflected between the first electrode and the second electrode, and the light is extracted from a second substrate (a top surface) opposite to the first substrate. In general, the transparent conductive material used for the second electrode has a resistance value higher than that of a metallic material. Therefore, in a larger organic light-emitting display unit, display performance may decrease from an end region to a central region in a display section, under influence of a voltage drop. When the thickness of the second electrode is increased, the resistance value decreases, which reduces the voltage drop in the display surface. In this case, however, visible light transmittance of the second electrode decreases, which leads to a reduction in light extraction efficiency of the light emitting element.

To address such an issue, the following technique has been proposed. In this technique, an auxiliary wiring is formed on a second substrate, and the auxiliary wiring is electrically connected to a second electrode of an organic light emitting element, so that a voltage drop of the second electrode is reduced (for example, see Japanese Unexamined Patent Application Publication No. 2007-141844). For example, the auxiliary wiring may be electrically connected to a common power supply line through a wiring provided in a first substrate.

### SUMMARY

However, even if the auxiliary wiring is provided, voltage may not be uniformly applied to the second electrode in a display region, which may cause display failure.

It is desirable to provide a display unit and an electronic apparatus that are capable of suppressing occurrence of display failure on an entire surface in a display region.

According to an embodiment of the present technology, there is provided a display unit including: a plurality of light emitting elements provided in a display region of a first substrate, and including a first electrode, a light emitting layer, and a second electrode in this order on the first substrate; an auxiliary wiring provided on a second substrate facing the first substrate with the light emitting elements interposed therebetween, and extending from the display region to a peripheral region surrounding the display region; a first pillar configured to electrically connect the auxiliary wiring and the second electrode of the light emitting elements; and a second pillar configured to electrically connect the auxiliary wiring and a peripheral electrode provided in the peripheral region of the first substrate.

According to an embodiment of the present technology, there is provided an electronic apparatus provided with a display unit, the display unit including: a plurality of light emitting elements provided in a display region of a first substrate, and including a first electrode, a light emitting layer, and a second electrode in this order on the first substrate; an auxiliary wiring provided on a second substrate facing the first substrate with the light emitting elements interposed therebetween, and extending from the display region to a peripheral region surrounding the display region; a first pillar configured to electrically connect the auxiliary wiring and the second electrode of the light emitting elements; and a second pillar configured to electrically connect the auxiliary wiring and a peripheral electrode provided in the peripheral region of the first substrate.

In the display unit or the electronic apparatus according to the above-described embodiment of the present technology, the second pillar electrically connecting the auxiliary wiring and the peripheral electrode is provided, separately from the first pillar electrically connected to the second electrode of the light emitting elements. Therefore, it is easy to uniformly apply voltage to the second electrode of all of the light emitting elements in the display region.

According to the display unit and the electronic apparatus in the above-described embodiments of the present technology, the second pillar electrically connecting the auxiliary wiring and the peripheral electrode is provided, in addition to the first pillar. Therefore, occurrence of display failure on an entire surface in the display region is allowed to be suppressed. It is to be noted that the effect described herein is provided only as an example without being limitative, and may be any of effects described in the present disclosure.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present technology, and are incorporated in and constitute a part of this specification. The drawings illustrate embodiments and, together with the specification, serve to describe the principles of the technology.

FIG. 1 is a cross-sectional diagram illustrating a configuration of a display unit according to an embodiment of the present technology.

FIG. 2 is a diagram illustrating a plane configuration of the display unit illustrated in FIG. 1.

FIG. 3 is a diagram illustrating an overall configuration of the display unit illustrated in FIG. 1.

FIG. 4 is a diagram illustrating an example of a pixel driving circuit illustrated in FIG. 3.

FIG. 5 is a plan view illustrating a configuration of a sealant between an element panel and a sealing panel illustrated in FIG. 1.

FIG. 6 is a plan view illustrating a configuration of a second contact electrode illustrated in FIG. 1.

FIG. 7A is a cross-sectional diagram illustrating a process of manufacturing the element panel of the display unit illustrated in FIG. 1.

FIG. 7B is a cross-sectional diagram illustrating a process following the process in FIG. 7A.

FIG. 7C is a cross-sectional diagram illustrating a process following the process in FIG. 7B.

FIG. 8 is a cross-sectional diagram illustrating a process of manufacturing the sealing panel of the display unit illustrated in FIG. 1.

FIG. 9A is a cross-sectional diagram illustrating a process of adhering the element panel illustrated in FIG. 7C and the sealing panel illustrated in FIG. 8 to each other.

FIG. 9B is a cross-sectional diagram illustrating a process following the process in FIG. 9A.

FIG. 9C is a cross-sectional diagram illustrating a process following the process in FIG. 9B.

FIG. 10 is a cross-sectional diagram illustrating a configuration of a peripheral region in a display unit according to a modification.

FIG. 11 is a plan view illustrating a schematic configuration of a module including the display unit illustrated in FIG. 1.

FIG. 12A is a perspective view illustrating an appearance of Application example 1.

FIG. 12B is another perspective view illustrating the appearance of Application example 1.

FIG. 13 is a perspective view illustrating an appearance of Application example 2.

FIG. 14 is a perspective view illustrating an appearance of Application example 3.

FIG. 15A is a perspective view illustrating an appearance of Application example 4 when viewed from front.

FIG. 15B is a perspective view illustrating an appearance of Application example 4 when viewed from back.

FIG. 16 is a perspective view illustrating an appearance of Application example 5.

FIG. 17 is a perspective view illustrating an appearance of Application example 6.

FIG. 18A is a diagram illustrating a closed state of Application example 7.

FIG. 18B is a diagram illustrating an open state of Application example 7.

### DETAILED DESCRIPTION

An embodiment of the present technology will be described below in detail with reference to the drawings. It is to be noted that the description will be provided in the following order.

1. Embodiment (a display unit)
2. Modification (an example in which a thickness of a pillar in a peripheral region is larger than a thickness of a pillar in a display region)
3. Application examples

### Embodiment

### [Overall Configuration of Display Unit 1]

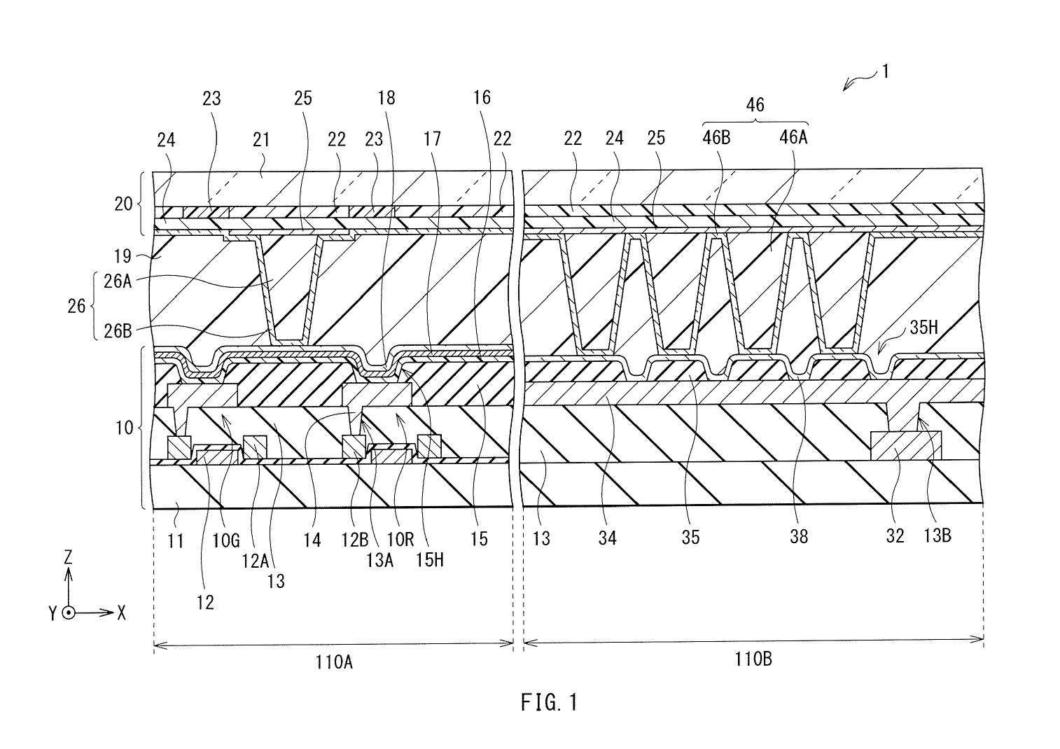

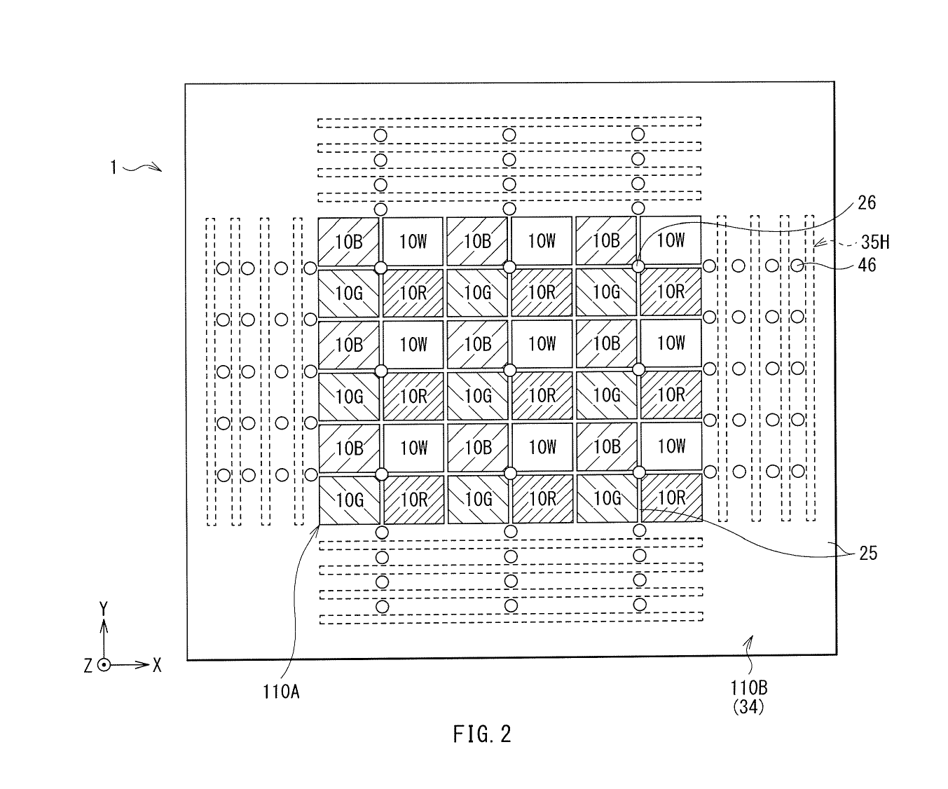

FIG. 1 illustrates a cross-sectional configuration of an organic EL display unit (a display unit 1) according to an embodiment of the present technology. FIG. 2 illustrates a plane configuration of the display unit 1. The display unit 1 includes an element panel 10 and a sealing panel 20. The display unit 1 may be a so-called top-emission-type display unit in which light passing through the sealing panel 20 is extracted. The display unit 1 may be a large display unit, and may have a size of, for example, 32 inches or more.

The element panel 10 includes an organic light emitting element 10R generating red light, an organic light emitting element 10G generating green light, an organic light emitting element 10B generating blue light, and an organic light emitting element 10W generating white light which are provided on a display region 110A of an element substrate 11 (a first substrate) (FIG. 2). The organic light emitting elements 10R, 10G, 10B, and 10W may include, for example, a first electrode 14, an organic layer 16, a high-resistive layer 17, and a second electrode 18 in this order on the element substrate 11 (FIG. 1). FIG. 1 illustrates a configuration of each of the organic light emitting elements 10R and 10G. A configuration of each of the organic light emitting elements 10B and 10W is substantially the same as this configuration. A thin-film transistor (TFT) 12 and a flattening layer 13 are provided between the element substrate 11 and each of the organic light emitting elements 10R, 10G, 10B, and 10W. The organic light emitting elements 10R, 10G, 10B, and 10W are covered by a filling resin layer 19 provided between these devices and the sealing panel 20. The sealing panel 20 includes a sealing substrate 21 (a second substrate) facing the element substrate 11. A light-shielding layer 22, a color filter 23, an overcoat layer 24, and an auxiliary wiring 25 are provided in this order on a surface, which faces the element substrate 11, of the sealing substrate 21.

In the display region 110A of the display unit 1, a pillar 26 (a first pillar) is provided between the element panel 10 and the sealing panel 20. The auxiliary wiring 25 in the sealing panel 20 and the second electrode 18 in the element panel 10 are electrically connected through the pillar 26.

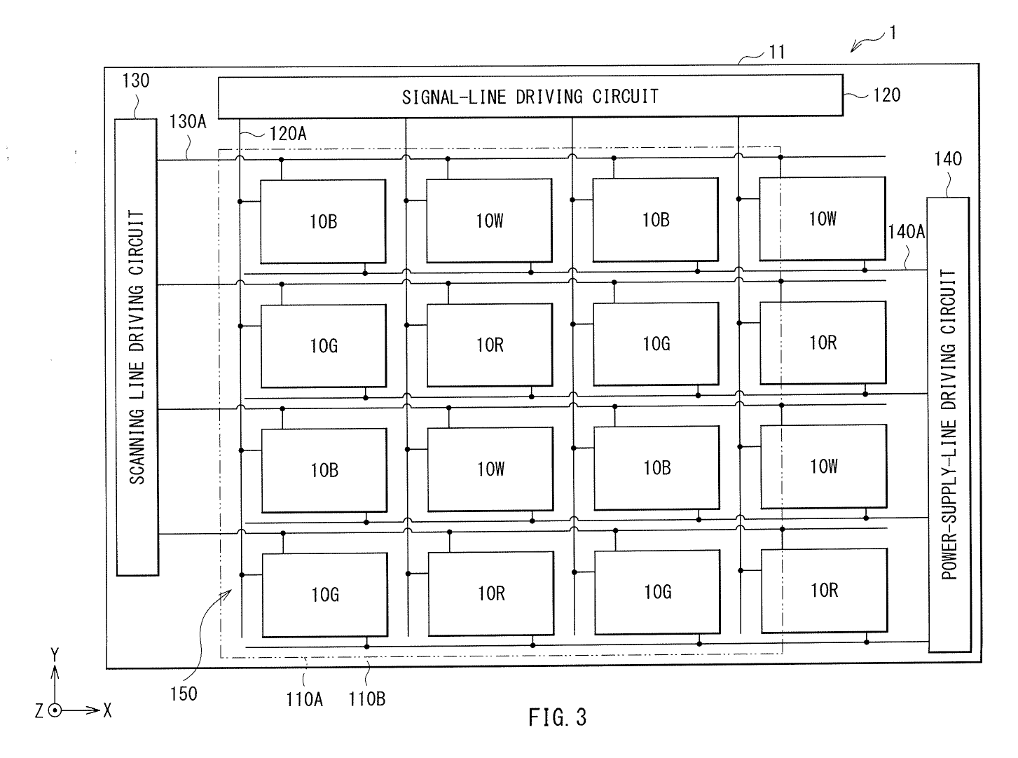

FIG. 3 illustrates an overall configuration of the display unit 1. In the display region 110A provided in a central part of the display unit 1, the organic light emitting elements 10R, 10G, 10B, and 10W are arranged two-dimensionally in a matrix. For example, the organic light emitting elements 10R, 10G, 10B, and 10W may each correspond to a sub-pixel, and the sub-pixels of four colors form one pixel. Provided in a peripheral region 110B surrounding the display region 110A may be, for example, a signal-line driving circuit 120, a scanning-line driving circuit 130, and a power-supply-line driving circuit 140 that are drivers for image display.

In the display region 110A, a pixel driving circuit 150 is formed together with the plurality of organic light emitting elements 10R, 10G, 10B, and 10W. The pixel driving circuit 150 is provided to drive the organic light emitting elements 10R, 10G, 10B, and 10W. In the pixel driving circuit 150, a plurality of signal lines 120A (120A1, 120A2, . . . , 120Am, . . . ) are arranged in a column direction (a Y direction). Further, in the pixel driving circuit 150, a plurality of scanning lines 130A (130A1, . . . , 130An, . . . ) and a plurality of power supply lines 140A (140A1, . . . , 140An, . . . ) are arranged in a row direction (an X direction). At an intersection of the signal line 120A and the scanning line 130A, the organic light emitting element 10R, 10G, 10B, or 10W is provided. Both ends of the signal line 120A are connected to the signal-line driving circuit 120, both ends of the scanning line 130A are connected to the scanning-line driving circuit 130, and both ends of the power supply line 140A are connected to the power-supply-line driving circuit 140.

The signal-line driving circuit 120 supplies each of the organic light emitting elements 10R, 10G, 10B, and 10W selected through the signal line 120A, with a signal voltage of an image signal in accordance with luminance information supplied from a signal supply source (not illustrated). The scanning-line driving circuit 130 includes components such as a shift register that sequentially shifts (transfers) a start pulse in synchronization with an inputted clock pulse. When writing the image signal to each of the organic light emitting elements 10R, 10G, 10B, and 10W, the scanning-line driving circuit 130 scans the organic light emitting elements 10R, 10G, 10B, and 10W row by row, and sequentially supplies a scanning signal to each of the scanning lines 130A. The signal line 120A is supplied with the signal voltage from the signal-line driving circuit 120, and the scanning line 130A is supplied with the scanning signal from the scanning-line driving circuit 130.

The power-supply-line driving circuit 140 includes components such as a shift register that sequentially shifts (transfers) a start pulse in synchronization with an inputted clock pulse. The power-supply-line driving circuit 140 appropriately supplies either of a first electric potential and a second electric potential that are different from each other, to the both ends of each of the power supply lines 140A, in synchronization with the row-by-row scanning by the scanning-line driving circuit 130. As a result, a conducting state or a non-conducting state of a transistor Tr1 to be described later is selected.

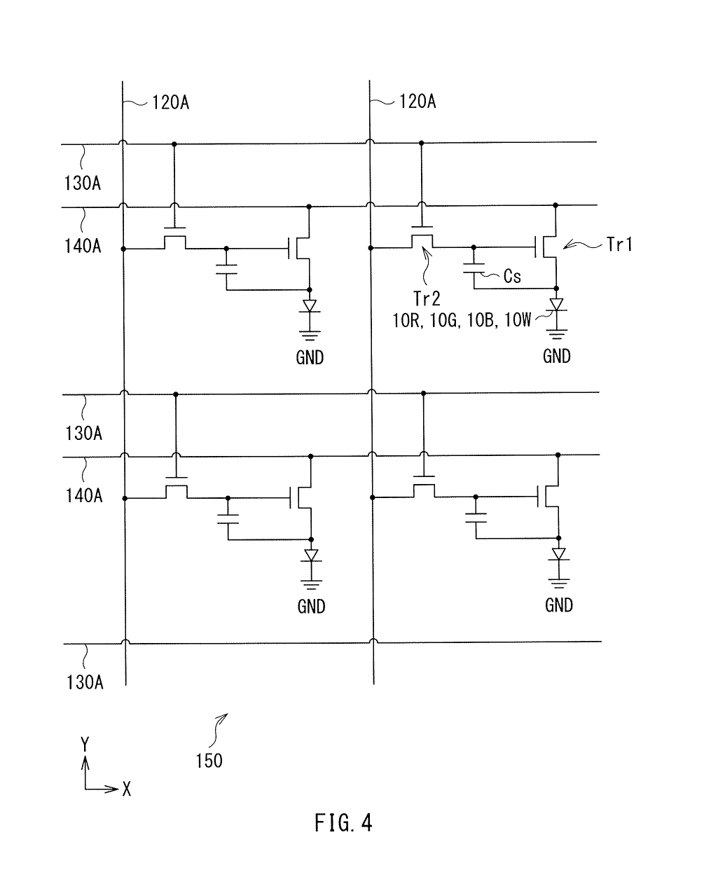

FIG. 4 illustrates a configuration example of the pixel driving circuit 150. The pixel driving circuit 150 is an active drive circuit that includes the transistor Tr1, a transistor Tr2, a capacitor (a retention capacitor) Cs, and the organic light emitting elements 10R, 10G, 10B, and 10W. Each of the organic light emitting elements 10R, 10G, 10B, and 10W is connected to the transistor Tr1 in series, between the power supply line 140A and a common power supply line (GND). Each of the transistor Tr1 and the transistor Tr2 may have an inverted staggered structure (a so-called bottom-gate type), or may have a staggered structure (a top-gate type).

Of the transistor Tr2, for example, a drain electrode may be connected to the signal line 120A, and may be supplied with the image signal from the signal-line driving circuit 120. Further, a gate electrode of the transistor Tr2 may be connected to the scanning line 130A, and may be supplied with the scanning signal from the scanning-line driving circuit 130. Furthermore, a source electrode of the transistor Tr2 may be connected to a gate electrode of the transistor Tr1.

Of the transistor Tr1, for example, a drain electrode may be connected to the power supply line 140A, and may be set at either the first electric potential or the second electric potential by the power-supply-line driving circuit 140. A source electrode of the transistor Tr1 may be connected to the organic light emitting element 10R, 10G, 10B, or 10W.

The retention capacitor Cs is formed between the gate electrode (the source electrode of the transistor Tr2) of the transistor Tr1 and the source electrode of the transistor Tr1.

### [Main-Part Configuration of Display Unit 1]

Next, a detailed configuration of each of the element panel 10 and the sealing panel 20 will be described with reference to FIG. 1 and FIG. 2 again.

The element substrate 11 may be, for example, formed of glass, a plastic material, or the like capable of interrupting transmission of moisture (water vapor) and oxygen. The element substrate 11 is a support member where the organic light emitting elements 10R, 10G, 10B, and 10W are formed in an array on a main-surface side thereof. For a material of the element substrate 11, for example, any of a glass substrate, a quartz substrate, and a silicon substrate may be used. Examples of the glass substrate may include high-strain-point glass, soda glass (Na₂O.CaO.SiO₂), borosilicate glass (Na₂O.B₂O₃.SiO₂), forsterite (2MgO.SiO₂), and lead glass (Na₂O.PbO.SiO₂). The element substrate 11 may be configured by providing an insulating film on a surface of any of these glass substrate, quartz substrate, and silicon substrate. Other materials such as metallic foil and a film or sheet made of resin may also be used for the element substrate 11. Examples of the resin may include organic polymers such as polymethyl methacrylate (PMMA), polyvinyl alcohol (PVA), polyvinyl phenol (PVP), polyether sulfone (PES), polyimide, polycarbonate, polyethylene terephthalate (PET), and polyethylene naphthalate (PEN). In the top emission type, light is extracted from the sealing substrate 21 side and therefore, the element substrate 11 may be formed of either a transparent material or a non-transparent material. For the sealing substrate 21, the same material as the material of the element substrate 11 may be used, or a different material may be used. Further, the element substrate 11 may be formed of a flexible material.

The TFT 12 may be, for example, a transistor corresponding to either the above-described transistor Tr1 or Tr2, and may serve as an active element of the organic light emitting elements 10R, 10G, 10B, or 10W. For example, the TFT 12 may have a gate electrode, a gate insulating film, a source electrode, a drain electrode, and a semiconductor layer. For example, the source electrode and the drain electrode of the TFT 12 may be electrically connected to a wiring 12B through an interlayer insulating film 12A made of silicon oxide or the like. For example, when the TFT 12 is the transistor Tr2, the wiring 12B may be connected to the signal line 120A. For example, when the TFT 12 is the transistor Tr1, the wiring 12B may be connected to the electrode (the first electrode 14) of the organic light emitting elements 10R, 10G, 10B, or 10W through a connection hole 13A of the flattening layer 13. For the interlayer insulating film 12A, for example, an organic material such as polyimide, or an inorganic material such as silicon oxide (SiO₂) and silicon nitride (SiN) may be used. For example, a SiO₂-based material such as boro-phosphosilicate glass (BPSG), PSG, BSG, AsSG, SiON, spin on glass (SOG), low-melting-point glass, and glass paste may also be used for the interlayer insulating film 12A. The wiring 12B may be configured of, for example, aluminum (Al) or an aluminum-copper (Cu) alloy.

The flattening layer 13 is provided to flatten a surface of the element substrate 11 where the TFT 12 is formed. In the flattening layer 13, the connection hole 13A that is minute and provided to connect the wiring 12B and the first electrode 14 is formed. Therefore, the flattening layer 13 may be preferably configured of a material with favorable pattern accuracy. When a material having a low water absorption rate is used for the flattening layer 13, it is possible to prevent the organic light emitting elements 10R, 10G, 10B, and 10W from deteriorating due to moisture. For example, an organic material such as polyimide may be used for the flattening layer 13. It is also possible to suppress deterioration of the TFT 12, by adding a function of blocking blue light or UV light, to the flattening layer 13.

A partition 15 is disposed between the organic light emitting elements 10R, 10G, 10B, and 10W next to each other. Arrangement of the organic light emitting elements 10R, 10G, 10B, and 10W is not limited in particular. For example, the organic light emitting elements 10R, 10G, 10B, and 10W may be in a stripe arrangement, a diagonal arrangement, a delta arrangement, a rectangle arrangement, etc.

The first electrodes 14 of the organic light emitting elements 10R, 10G, 10B, and 10W are disposed away from each other on the flattening layer 13. The first electrode 14 has a function of serving as an anode electrode and a function of serving as a reflective layer, and may be desirably configured of a material having high reflectance and high hole injection ability. The first electrode 14 as described above may have, for example, a thickness in a lamination direction (hereinafter simply referred to as “thickness”) of 0.1 μm or more and 1 μm or less. Examples of the material of the first electrode 14 may include a simple substance of metallic elements such as chromium (Cr), gold (Au), platinum (Pt), nickel (Ni), copper (Cu), molybdenum (Mo), tungsten (W), titanium (Ti), tantalum (Ta), aluminum (Al), iron (Fe), and silver (Ag), or an alloy thereof. The first electrode 14 may be configured by laminating such metal films. For the first electrode 14, an Ag—Pd—Cu alloy or an Al-neodymium (Nd) alloy may also be used. The Ag—Pd—Cu alloy is an alloy in which 0.3 wt % to 1 wt % of palladium (Pd) and 0.3 wt % to 1 wt % of copper are contained in silver. A material having a high work function may be preferably used for the first electrode 14. However, metal having a low work function such as aluminum and aluminum alloys may be used for the first electrode 14, by appropriately selecting the organic layer 16 (in particular, a hole injection layer to be described later).

A part from a top surface (a surface facing the second electrode 18) to side surfaces of the first electrode 14 is covered with the partition 15. An opening 15H of the partition 15 is a light emission region of each of the organic light emitting elements 10R, 10G, 10B, and 10W. The partition 15 serves to control the light emission region precisely to a desirable shape, and to secure insulation between the first electrode 14 and the second electrode 18. For example, an organic material such as polyimide, or an inorganic material such as silicon oxide (SiO₂), silicon nitride (SiNₓ), and silicon oxynitride (SiON) may be used for the partition 15. The partition 15 may have a thickness of, for example, 50 nm to 2,500 nm.

The organic layer 16 may be provided, for example, to be common to all of the organic light emitting elements 10R, 10G, 10B, and 10W. The organic layer 16 may include a hole injection layer, a hole transport layer, the light emitting layer, an electron transport layer, and an electron injection layer (none of these layers are illustrated) in this order from the first electrode 14 side. The organic layer 16 may be configured of the hole transport layer, the light emitting layer, and the electron transport layer. In this case, the light emitting layer may also serve as the electron transport layer. A plurality of such laminated structures (so-called tandem units) each including a series of layers may be laminated with a connection layer interposed therebetween, to configure the organic layer 16. For example, the tandem units for the respective colors of red, green, blue, and white may be provided and laminated to configure the organic layer 16.

The hole injection layer is a buffer layer provided to increase hole injection efficiency and to prevent leakage. For example, the hole injection layer may have a thickness of 1 nm or more and 300 nm or less, and may be configured of a hexaazatriphenylene derivative expressed by the following chemical formula 1 or chemical formula 2.

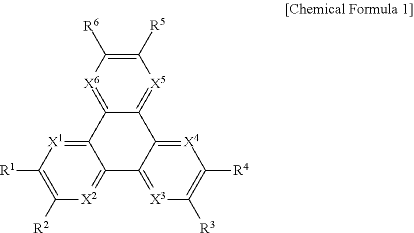

(In the chemical formula 1, R1 to R6 are each independently a substituent group selected from hydrogen, halogen, a hydroxyl group, an amino group, an arylamino group, a substituted or unsubstituted carbonyl group with carbon number of 20 or less, a substituted or unsubstituted carbonyl ester group with carbon number of 20 or less, a substituted or unsubstituted alkyl group with carbon number of 20 or less, a substituted or unsubstituted alkenyl group with carbon number of 20 or less, a substituted or unsubstituted alkoxyl group with carbon number of 20 or less, a substituted or unsubstituted aryl group with carbon number of 30 or less, a substituted or unsubstituted heterocyclic group with carbon number of 30 or less, a nitrile group, a cyano group, a nitro group, and a silyl group. Rms (m=1 to 6) next to each other may be coupled to each other through a cyclic structure. Further, X1 to X6 are each independently a carbon or nitrogen atom.)

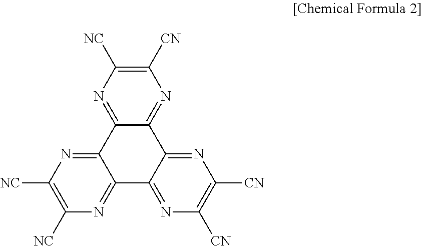 [SMILES: N#Cc1nc2c3nc(C#N)c(C#N)nc3c3nc(C#N)c(C#N)nc3c2nc1C#N]

The hole transport layer is provided to increase hole transport efficiency for the light emitting layer. For example, the hole transport layer may have a thickness of about 40 nm, and may be configured of 4,4′,4″-tris(3-methylphenylphenylamino)triphenylamine (m-MTDATA), or α-naphthylphenyldiamine (α NPD).

For example, the light emitting layer may be provided for white light emission, and have, for example, a laminated body including a red light emitting layer, a green light emitting layer, and a blue light emitting layer (none of these layers are illustrated) between the first electrode 14 and the second electrode 18. The red light emitting layer, the green light emitting layer, and the blue light emitting layer emit light of red, green, and blue, respectively, by electron-hole recombination caused by application of an electric field. In this recombination, part of holes injected from the first electrode 14 through the hole injection layer and the hole transport layer is recombined with part of electrons injected from the second electrode 18 through the electron injection layer and the electron transport layer.

The red light emitting layer may include, for example, one or more of a red luminescent material, a hole-transporting material, an electron-transporting material, and a both-carrier transporting material. The red luminescent material may be either a fluorescent material or a phosphorescent material. The red light emitting layer may have, for example, a thickness of about 5 nm, and may be configured of 4,4-bis(2,2-diphenylvinyl)biphenyl (DPVBi) mixed with 30 wt % of 2,6-bis[(4′-methoxydiphenylamino)styryl]-1,5-dicyanonaphthalene (BSN).

The green light emitting layer may include, for example, one or more of a green luminescent material, a hole-transporting material, an electron-transporting material, and a both-carrier transporting material. The green luminescent material may be either a fluorescent material or a phosphorescent material. The green light emitting layer may have, for example, a thickness of about 10 nm, and may be configured of DPVBi mixed with 5 wt % of coumarin 6.

The blue light emitting layer may include, for example, one or more of a blue luminescent material, a hole-transporting material, an electron-transporting material, and a both-carrier transporting material. The blue luminescent material may be either a fluorescent material or a phosphorescent material. The blue light emitting layer may have, for example, a thickness of about 30 nm, and may be configured of DPVBi mixed with 2.5 wt % of 4,4′-bis[2-{4-(N,N-diphenylamino)phenyl}vinyl]biphenyl (DPAVBi).

The electron transport layer is provided to increase electron transport efficiency for the light emitting layer, and may be configured of, for example, 8-hydroxyquinolinealuminum (Alq3) having a thickness of about 20 nm. The electron injection layer is provided to increase electron injection efficiency to the light emitting layer, and may be configured of, for example, LiF, Li₂O, or the like having a thickness of about 0.3 nm.

The high-resistive layer 17 is used to prevent occurrence of a short circuit between the first electrode 14 and the second electrode 18, and is provided to be common to all of the organic light emitting elements 10R, 10G, 10B, and 10W. The high-resistive layer 17 has electric resistance higher than electric resistance of each of the first electrode 14 and the second electrode 18. The high-resistive layer 17 has a charge transport function or a charge injection function. When a particle (foreign matter) or projection is deposited on the first electrode 14 and the organic light emitting elements 10R, 10G, 10B, and 10W are formed in such a state, a short circuit may occur due to contact between the first electrode 14 and the second electrode 18. The high-resistive layer 17 makes it possible to prevent such contact between the first electrode 14 and the second electrode 18.

The high-resistive layer 17 may be preferably configured of, for example, a material having electric resistivity of 1×10⁶ Ω·m or more and 1×10⁸ Ω·m or less. This is because, within this range, it is possible to prevent occurrence of a short circuit sufficiently, while keeping a drive voltage low. The high-resistive layer 17 may be configured of, for example, niobium oxide (Nb₂O₅), titanium oxide (TiO₂), molybdenum oxide (MoO₂, MoO₃), tantalum oxide (Ta₂O₅), hafnium oxide (HfO), magnesium oxide (MgO), IGZO (InGaZnOₓ), a mixture of niobium oxide and titanium oxide, a mixture of titanium oxide and zinc oxide (ZnO), a mixture of a silicon oxide (SiO₂) and tin oxide (SnO₂), and a mixture in which zinc oxide is mixed with one or more of magnesium oxide, silicon oxide, and aluminum oxide (Al₂O₃). The high-resistive layer 17 may be configured by appropriately combining some of these materials. The high-resistive layer 17 having a value of a refractive index closer to those of the organic layer 16 and the second electrode 18 may be preferably used. For example, the value of the refractive index may preferably be 1.7 or more, and more preferably, may be 1.9 or more. This improves external quantum efficiency of the light emitting layer of the organic layer 16. The high-resistive layer 17 may have a thickness of, for example, about 100 nm to about 1,000 nm.

The second electrode 18 is paired with the first electrode 14, with the organic layer 16 interposed therebetween. For example, the second electrode 18 may be provided on the electron injection layer, to be common to all of the organic light emitting elements 10R, 10G, 10B, and 10W. The second electrode 18 may have, for example, a function of serving as a cathode electrode and a function of serving as a light transmission layer, and may be desirably configured of a material having high conductivity and high optical transmittance. Therefore, the second electrode 18 may be configured of, for example, an alloy of aluminum (Al), magnesium (Mg), silver (Ag), calcium (Ca), or sodium (Na). In particular, an alloy of magnesium and silver (a Mg—Ag alloy) may be preferably used, because the Mg—Ag alloy has both conductivity and low absorption in form of a thin film. The ratio between magnesium and silver in the Mg—Ag alloy is not limited in particular, but may be preferably in a range in which an Mg to Ag film-thickness ratio is from 20:1 to 1:1. Further, an alloy of aluminum (Al) and lithium (Li) (an Al—Li alloy) may also be used for the material of the second electrode 18. Furthermore, a material such as indium tin oxide (ITO), zinc oxide (ZnO), alumina-doped zinc oxide (AZO), gallium-doped zinc oxide (GZO), indium zinc oxide (IZO), indium titanium oxide (ITiO), and indium tungsten oxide (IWO) may also be used. As will be described later in detail, the auxiliary wiring 25 is provided in the display unit 1 and therefore, it is possible to reduce the thickness of the second electrode 18. The second electrode 18 may have a thickness of, for example, about 10 nm to about 500 nm. The second electrode 18 and the high-resistive layer 17 also have a function of preventing entrance of moisture into the organic layer 16.

The filling resin layer 19 provided between the element panel 10 and the sealing panel 20 is used to prevent entrance of moisture into the organic layer 16 and to increase mechanical strength of the display unit 1. The filling resin layer 19 is provided to cover the second electrode 18. The filling resin layer 19 may preferably have optical transmittance of about 80%. In addition, the filling resin layer 19 may preferably have a thickness of 3 μm to 20 μm, and more preferably, of 5 μm to 15 μm. If the thickness of the filling resin layer 19 is larger than 20 μm, a distance between the color filter 23 and each of the organic light emitting elements 10R, 10G, 10B, and 10W may become longer, and luminance in an oblique direction with respect to the element substrate 11 may become lower than luminance in a front direction. In addition, a viewing angle may become narrow, because of a reduction in chromaticity due to occurrence of color mixture. On the other hand, if the thickness of the filling resin layer 19 is smaller than 3 μm, when the sealing panel 20 and the element panel 10 are adhered to each other while foreign matter is sandwiched therebetween, this foreign matter easily touches the organic light emitting elements 10R, 10G, 10B, and 10W. The organic light emitting elements 10R, 10G, 10B, and 10W may be pressurized by the foreign matter, which may cause a dark spot such as pixel omission.

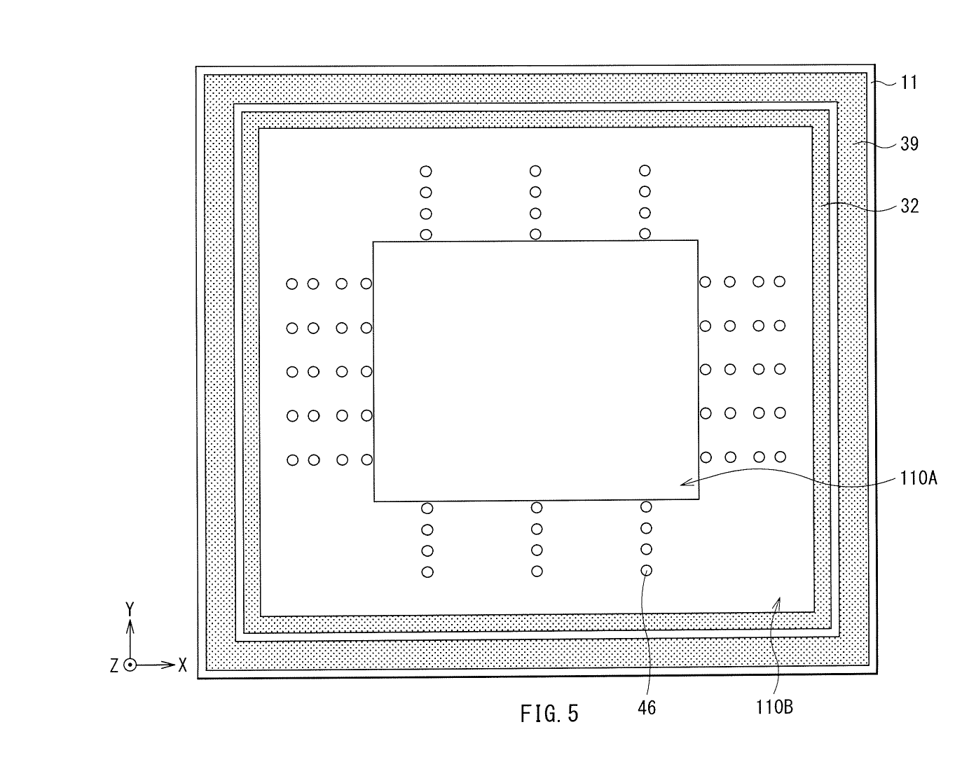

As illustrated in FIG. 5, a sealant 39 is provided in a peripheral edge of the display unit 1. The sealant 39 is provided to surround the filling resin layer 19 between the element panel 10 and the sealing panel 20, and to adhere the element panel 10 and the sealing panel 20 to each other. The sealant 39 also serves to prevent entrance of moisture from outside into the display region 110A.

The light-shielding layer 22 of the sealing panel 20 is a so-called black matrix (BM). The light-shielding layer 22 may be, for example, patterned into a matrix to match with the arrangement of the organic light emitting elements 10R, 10G, 10B, and 10W in the display region 110A. The light-shielding layer 22 is provided on the entire surface in the peripheral region 110B. The light-shielding layer 22 may be preferably configured of carbon black. A material having both light blocking characteristics and conductivity such as chromium and graphite may also be used for the light-shielding layer 22. Alternatively, the light-shielding layer 22 may be configured of a thin-film filter utilizing thin-film interference. For example, this thin-film filter may be configured by laminating one or more thin films made of materials such as metal, metal nitride, and metal oxide, to reduce the light by causing thin-film interference. Examples of such a thin-film filter may include a film in which 65 nm of silicon nitride (SiN), 20 nm of amorphous silicon (a-Si), and 50 nm or more of molybdenum (Mo) are laminated in this order from the sealing substrate 21 side. The examples may further include a film in which 45 nm of molybdenum oxide (MoOₓ), 10 nm of molybdenum, 40 nm of molybdenum oxide, and 50 nm or more of molybdenum (Mo) are laminated in this order from the sealing substrate 21 side.

The color filter 23 may include, for example, a red filter, a green filter, a blue filter, and a white filter that are in a color arrangement corresponding to the patterns of the light-shielding layer 22 and the organic light emitting elements 10R, 10G, 10B, and 10W. The color filter 23 may be provided at a position overlapping the light-shielding layer 22. The red filter, the green filter, the blue filter, and the white filter may each be configured of, for example, resin mixed with a pigment or a dye. By selecting the kind of this pigment or dye appropriately, the red filter, the green filter, the blue filter, and the white filter are each adjusted so that optical transmittance in a wavelength region of each of red, green, blue, and white becomes high. Optical transmittance of the color filter 23 is low in regions other than the wavelength regions intended for red, green, blue, and white. The color filter 23 may have a thickness of, for example, 1 μm to 4 μm. The color filter 23 may be provided on a surface on either side (a surface facing the element substrate 11 or a surface opposite thereto) of the sealing substrate 21. However, the color filter 23 may be preferably provided on the surface facing the element substrate 11. One reason for this is that the color filter 23 is allowed to be protected by the filling resin layer 19 or the auxiliary wiring 25, without being exposed on the surface. Another reason is that the distance between the organic layer 16 and the color filter 23 becomes short, which makes it possible to avoid occurrence of color mixture due to entrance of light emitted from the organic layer 16 into the adjacent color filter of other color.

A surface (a surface facing the element substrate 11) of the color filter 23 is covered with the overcoat layer 24. The overcoat layer 24 is a coating agent used to increase flatness of the surface of the color filter 23 and to protect this surface. The overcoat layer 24 may be configured of, for example, an organic material such as resin or an inorganic material such as SiO, SiN, and ITO.

The auxiliary wiring 25 is provided to electrically connect a wiring 32 to be described later, to the second electrode 18 of the organic light emitting elements 10R, 10G, 10B, and 10W. The auxiliary wiring 25 may be preferably configured of a material having high conductivity and resistant to oxidizing in the air. Specific examples of the material of the auxiliary wiring 25 may include aluminum (Al), silver (Ag), gold (Au), copper (Cu), chromium (Cr), zinc (Zn), iron (Fe), tungsten (W), and cobalt (Co). Aluminum is relatively prone to be oxidized and therefore, the auxiliary wiring 25 may be preferably configured by covering a surface of aluminum with molybdenum (Mo) or titanium (Ti). It is possible to suppress occurrence of a so-called IR drop, by providing the above-described auxiliary wiring 25. This will be described below.

In a top-emission-type display unit, a light-transmissive conductive film is used for a second electrode. However, the light-transmissive conductive film has high resistivity and therefore, a rate of increase in wiring resistance in accordance with a distance from a feeding point to each of organic light emitting elements is large. In addition, the second electrode may preferably have a small thickness, which further increases the resistance of the second electrode. Therefore, if the distance between each of the organic light emitting elements and the feeding point becomes long, an effective voltage applied to the organic light emitting element considerably drops and luminance also greatly decreases. It is possible to suppress occurrence of such an IR drop, by providing the auxiliary wiring 25 serving as a current bypass between the second electrode 18 and the feeding point of the second electrode 18.

As illustrated in FIG. 2, the auxiliary wiring 25 in the display region 110A may be provided, for example, in a matrix to overlap the light-shielding layer 22. The auxiliary wiring 25 may be extended only in one direction (strip shape). The conductive light-shielding layer 22 may be used to serve also as the auxiliary wiring 25. The material, thickness, width, etc. of the auxiliary wiring 25 may be appropriately adjusted according to factors such as a panel size, so that the auxiliary wiring 25 has electric resistivity lower than electric resistivity of the second electrode 18. The auxiliary wiring 25 is provided to extend from the display region 110A to the peripheral region 110B, and is electrically connected to the wiring 32 (FIG. 1) to be described later, in the peripheral region 110B. The auxiliary wiring 25 in the peripheral region 110B may be provided, for example, to surround the display region 110A. In the peripheral region 110B, the auxiliary wiring 25 may be provided without being patterned.

The pillar 26 becomes the feeding point for the second electrode 18, and electrically connects the second electrode 18 and the auxiliary wiring 25. The pillar 26 may include, for example, a formed member 26A in a tapered shape and a light-transmissive conductive film 26B that covers the formed member 26A. The conductive film 26B is in contact with the second electrode 18 at a tip of the formed member 26A, while being in contact with the auxiliary wiring 25 at a base end thereof. The formed member 26A is disposed in a region (a non light emission region) between the organic light emitting elements 10R, 10G, 10B, and 10W next to each other. In other words, the formed member 26A is provided between the second electrode 18 provided to extend on the partition 15 and the auxiliary wiring 25. The formed member 26A may be provided for one pixel (sub-pixels of four colors) (FIG. 2). Alternatively, one formed member 26A may be provided for each of the organic light emitting elements 10R, 10G, 10B, and 10W (not illustrated). The formed member 26A may be configured of, for example, a photosensitive resin material. The formed member 26A may be configured of, for example, a resin material such as acrylic resin, epoxy resin, and polyimide resin, which is mixed with electrically-conductive fine particles, so that the conductive film 26B is omitted. The formed member 26A may be in any shape. The formed member 26A may be, for example, in a tapered shape, a rectangular parallelepiped shape, or a circular cylindrical shape. It may only be necessary for the conductive film 26B to be in contact with the auxiliary wiring 25 while covering the formed member 26A. However, the conductive film 26B may be provided to be common to all of the pillars 26. The conductive film 26B may be configured of, for example, a conductive material having high optical transparency as with the above-described second electrode 18.

It may only be necessary for the pillar 26 to be in contact with the second electrode 18, by protruding, for example, about 3 μm to about 20 μm, preferably, about 5 μm to about 15 μm, from the sealing panel 20 side. The distance between the element panel 10 and the sealing panel 20 may also be defined by the size of the pillar 26. Using the pillar 26 that is elastic and deformable, the second electrode 18 of the element panel 10 and the auxiliary wiring 25 of the sealing panel 20 may be preferably connected to each other with reliability. If there are variations in the size of the formed pillars 26, the pillars 26 of larger sizes are sequentially brought into contact with the second electrode 18 of the element panel 10, when the sealing panel 20 is adhered to the element panel 10. The elastic and deformable pillar 26 is capable of absorbing these variations in size and therefore, it is possible to bring the second electrode 18 into contact with the smallest pillar 26 reliably. Further, it is also possible to prevent damage, by absorbing pressure applied to the large pillars 26. The distance between the element panel 10 and the sealing panel 20 may also be adjusted by the thickness of the color filter 23 between the light-shielding layer 22 and the overcoat layer 24, in addition to the pillar 26. This distance may be adjusted by overlapping end parts of the red filter, the green filter, the blue filter, and the white filter next to each other.

In the peripheral region 110B of the display unit 1, the wiring 32 is provided, and the auxiliary wiring 25 is electrically connected to the wiring 32 through a pillar 46 (a second pillar), a second contact electrode 38, and a first contact electrode 34. A peripheral electrode according to an embodiment of the present technology corresponds to the first contact electrode 34, the second contact electrode 38, and the wiring 32. The wiring 32 is provided on the element substrate 11. The flattening layer 13, the first contact electrode 34, an insulating film 35, and the second contact electrode 38 are disposed in this order on the wiring 32.

As illustrated in FIG. 5, for example, the wiring 32 may be disposed inside the sealant 39, and may be provided at all sides of the element substrate 11. Of the wiring 32, one side is electrically connected to the second electrode 18 of the organic light emitting elements 10R, 10G, 10B, and 10W through the auxiliary wiring 25, and the other side may be electrically connected to, for example, a common power supply line (GND).

The flattening layer 13 on the wiring 32 is the same as the flattening layer 13 in the display region 110A, and a thickness as well as a material thereof are also the same as those of the flattening layer 13 in the display region 110A. The wiring 32 is connected to the first contact electrode 34 through a connection hole 13B of the flattening layer 13.

The first contact electrode 34 may be configured of, for example, the same material as that of the first electrode 14 of the organic light emitting elements 10R, 10G, 10B, and 10W, and may also have the same thickness as the thickness of the first electrode 14. The first contact electrode 34 may be provided, for example, on the entire surface in the peripheral region 110B (FIG. 2). For example, the insulating film 35 may be configured of the same material and may have the same thickness as those of the partition 15 in the display region 110A. The insulating film 35 has a plurality of connection holes 35H on the first contact electrode 34, and the second contact electrode 38 is in contact with the first contact electrode 34 in the plurality of connection holes 35H. The connection hole 35H may be preferably provided at a position facing a part between the pillars 46 next to each other. For example, the connection hole 35H may be provided to extend in a direction vertical to each side of the peripheral region 110B (FIG. 2). The connection hole 35H may be provided to extend in a direction orthogonal to each side of the peripheral region 110B (not illustrated). For example, the connection holes 35H each having a circular shape may be provided at the respective positions without being extended (not illustrated).

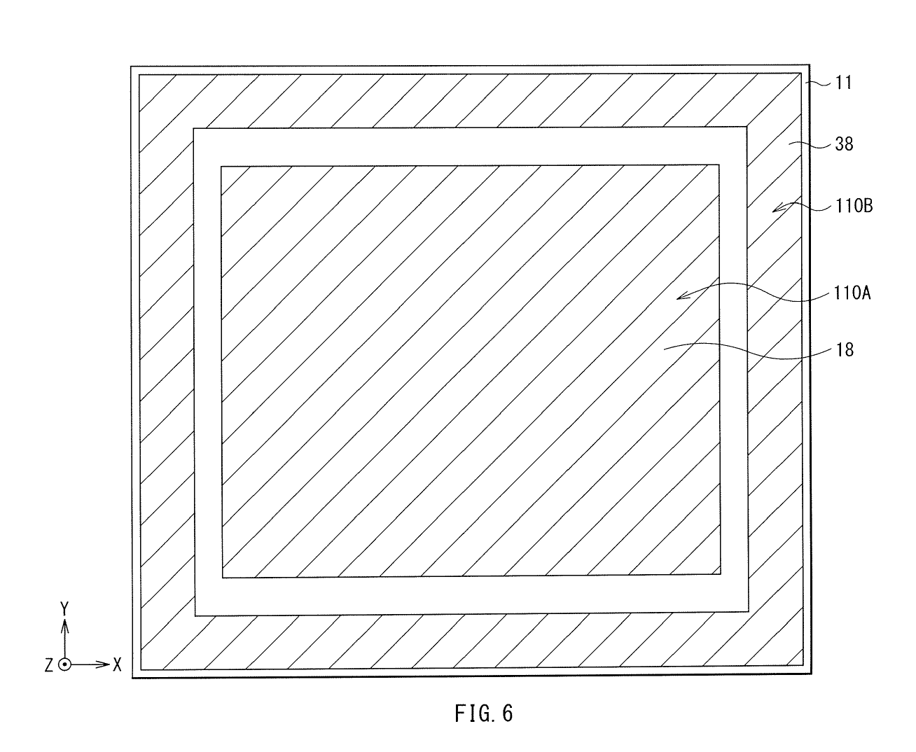

As illustrated in FIG. 6, for example, the second contact electrode 38 may be provided to surround the display region 110A, while covering the insulating film 35 as well as the connection holes 35H of the insulating film 35. The second contact electrode 38 is configured of the same material as that of the second electrode 18 of the organic light emitting elements 10R, 10G, 10B, and 10W, and has the same thickness as the thickness of the second electrode 18 as well. The second contact electrode 38 and the second electrode 18 may be integral with each other.

In the present embodiment, the pillar 46 (the second pillar) used to electrically connect the auxiliary wiring 25 and the second contact electrode 38 is provided between the sealing panel 20 and the element panel 10 in the peripheral region 110B. As will be described later in detail, this makes it possible to suppress display failure on the entire surface in the display region 110A.

The plurality of pillars 46 are provided at each of all sides of the peripheral region 110B. Distribution density of the pillars 46 in the peripheral region 110B may be preferably higher than distribution density of the pillars 26 in the display region 110A. The pillars 46 are provided inside the sealant 39 together with the wiring 32 (FIG. 5), and the filling resin layer 19 is provided around the pillars 46. The pillar 46 includes a formed member 46A in a tapered shape and a conductive film 46B covering the formed member 46A, as with the pillar 26. The conductive film 46B is in contact with the second contact electrode 38 at a tip of the formed member 46A, while being in contact with the auxiliary wiring 25 at a base end thereof. The formed member 46A is disposed on the insulating film 35. The formed member 46A and the conductive film 46B may be preferably configured of the same material as that of the formed member 26A and the same material as that of the conductive film 26B, respectively. Further, the formed member 46A may preferably have the same height (in a Z direction of FIG. 1) as that of the formed member 26A. The conductive film 46B may preferably have the same thickness (in the Z direction of FIG. 1) as that of the conductive film 26B. In other words, the pillar 46 and the pillar 26 may preferably be configured of the same material and may preferably have the same height. The formed member 46A may be configured of an electrically-conductive material, so that the conductive film 46B is omitted. The pillar 46 may be preferably elastic and deformable, as with the pillar 26. The formed member 46A may be in any shape. The formed member 46A may be, for example, in a tapered shape, a rectangular parallelepiped shape, or a circular cylindrical shape. It may only be necessary for the conductive film 46B to be in contact with the auxiliary wiring 25 while covering the formed member 46A. However, the conductive film 46B may be provided to be common to all of the pillars 46. For example, the plurality of pillars 46 may be electrically connected to one first contact electrode 34 through the second contact electrode 38. The insulating film 35 may have, for example, one connection hole 35H for one pillar 46.

In the peripheral region 110B, the overcoat layer 24 and the light-shielding layer 22 extending from the display region 110A are provided between the auxiliary wiring 25 and the sealing substrate 21.

### [Method of Manufacturing Display Unit 1]

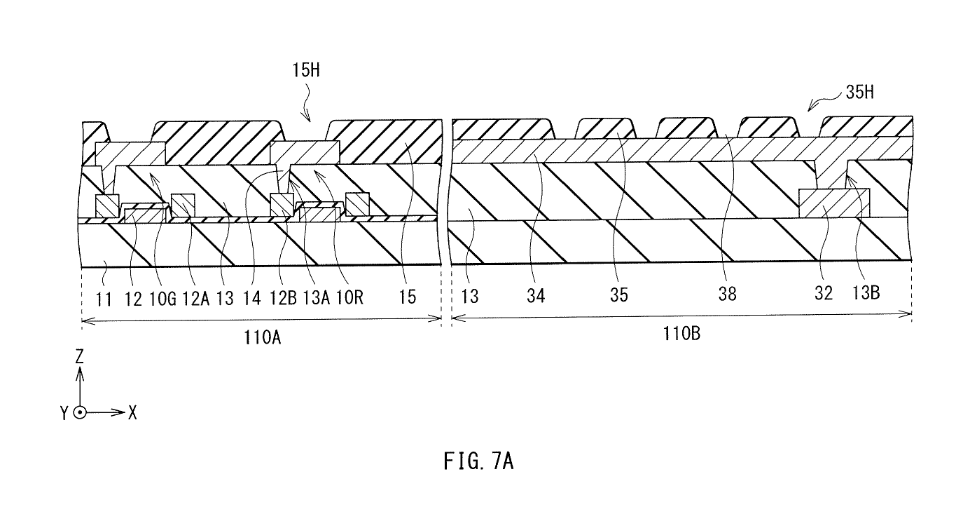

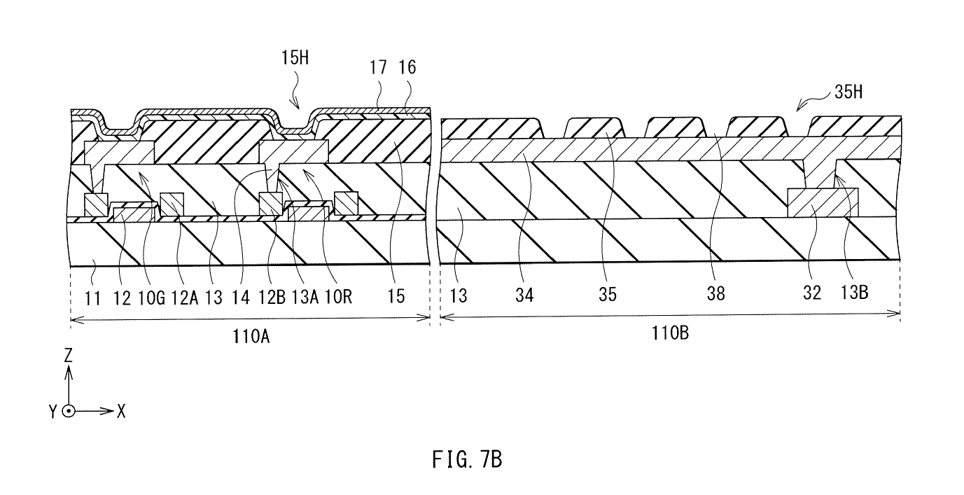

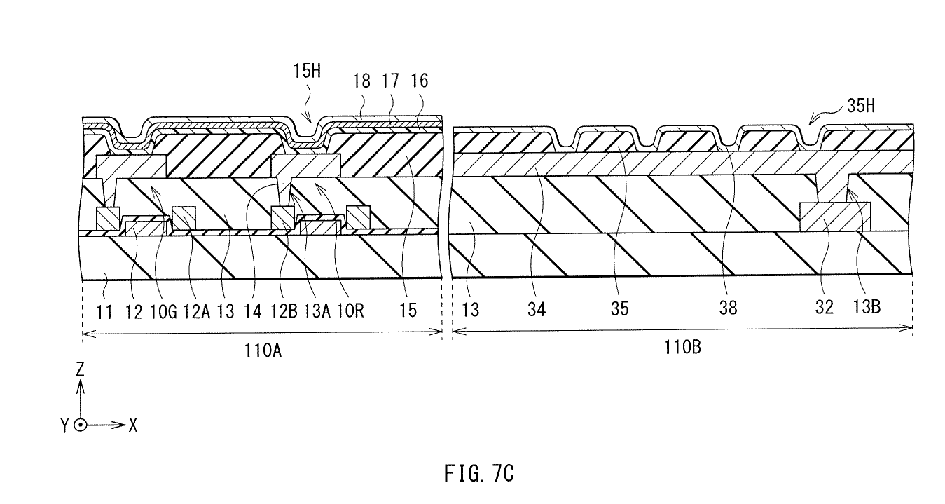

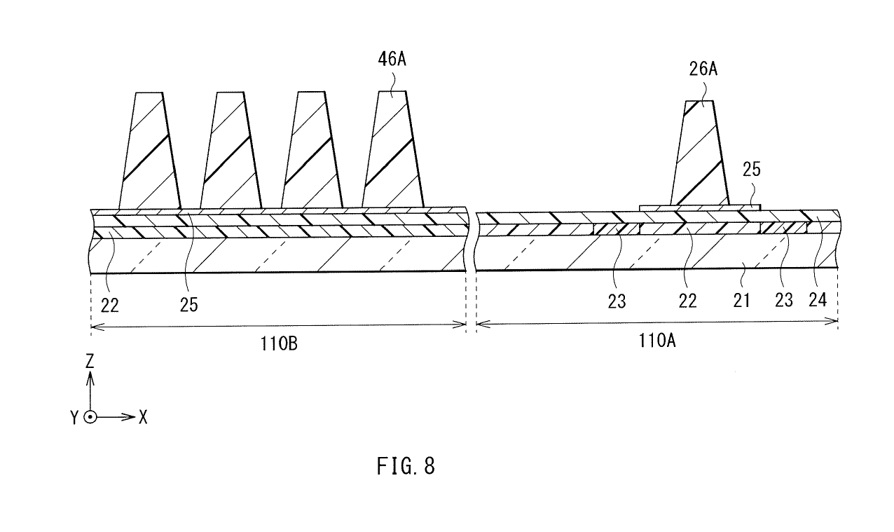

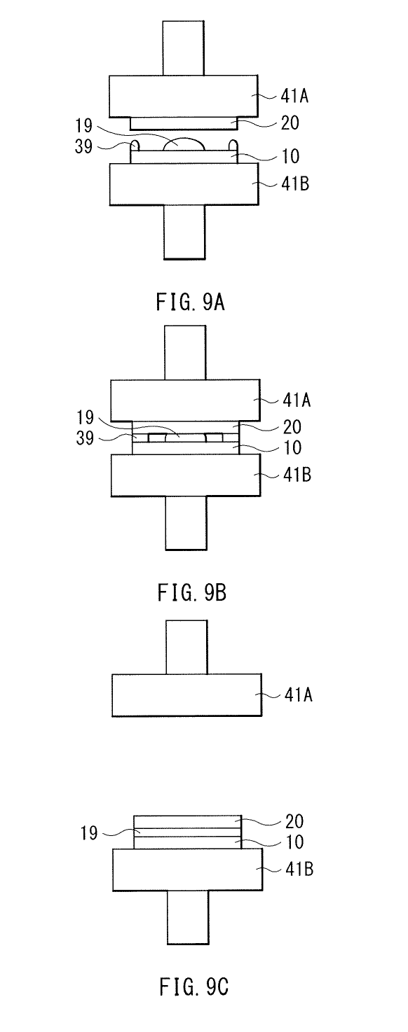

The display unit 1 may be manufactured, for example, by forming the element panel 10 and the sealing panel 20, and then adhering the element panel 10 and the sealing panel 20 to each other. Processes (FIGS. 7A to 7D) of forming the element panel 10, a process (FIG. 8) of forming the sealing panel 20, and processes (FIGS. 9A to 9C) of adhering the element panel 10 and the sealing panel 20 to each other will be described below in this order.

### [Method of Manufacturing Element Panel 10]

First, the TFT 12, the interlayer insulating film 12A, and the wiring 12B are formed in the display region 110A of the element substrate 11, and the wiring 32 is formed in the peripheral region 110B of the element substrate 11. Next, the flattening layer 13 is formed on the entire surface of the element substrate 11. The flattening layer 13 may be formed by, for example, any of chemical vapor deposition (CVD), coating, sputtering, various kinds of printing methods, and the like. In the flattening layer 13, the connection holes 13A and 13B are provided beforehand.

Next, a conductive film may be formed on the flattening layer 13 by, for example, sputtering, and then the formed conductive film may be patterned using a photolithography process, to form the first electrode 14 in the display region 110A and the first contact electrode 34 in the peripheral region 110B. Subsequently, for example, a silicon nitride film may be formed on the first electrode 14 and the flattening layer 13 by, for example, plasma CVD, and then the opening 15H and the connection hole 35H are provided in this silicon nitride film, to form the partition 15 and the insulating film 35 (FIG. 7A).

Next, the organic layer 16, which includes the light emitting layer, and the high-resistive layer 17 may be formed on the entire surface in the display region 110A on the element substrate 11 by, for example, physical vapor deposition (PVD) such as vacuum deposition (FIG. 7B). In this process, the peripheral region 110B is covered with a mask or the like. Next, the mask or the like is removed from the peripheral region 110B. Subsequently, a transparent conductive film extending from the display region 110A to the peripheral region 110B may be formed by PVD. As a result, the second electrode 18 is formed on the entire surface in the display region 110A, and the second contact electrode 38 is formed in the peripheral region 110B (FIG. 7C). The organic layer 16, the high-resistive layer 17, and the second electrode 18 may be formed by a printing method such as screen printing and ink-jet printing, laser transfer, coating, or the like. The laser transfer is a method of transferring the organic layer 16 to the element substrate 11, by emitting a laser to a laminated structure including a laser absorbing layer and the organic layer 16 formed on a transfer substrate.

### [Method of Manufacturing Sealing Panel 20]

The sealing panel 20 of the display unit 1 may be formed as follows, for example (FIG. 8). First, the material of the light-shielding layer 22 may be formed on the entire surface of the sealing substrate 21, and then may be patterned into a matrix by using, for example, a photolithography process. As a result, a plurality of openings are formed to match with the arrangement of the organic light emitting elements 10R, 10G, 10B, and 10W. Next, the red filter, the green filter, the blue filter, and the white filter are sequentially formed to be patterned on the sealing substrate 21 provided with the light-shielding layer 22, so that the color filter 23 is formed. Subsequently, the overcoat layer 24 is formed on the entire surface of the sealing substrate 21 and further, a conductive film is formed on the overcoat layer 24. Next, this conductive film in the display region 110A may be patterned into, for example, a matrix, to be connected to the conductive film in the peripheral region 110B. As a result, the auxiliary wiring 25 is formed.

After the auxiliary wiring 25 is provided, the pillar 26 and the pillar 64 are formed. Specifically, at first, for example, acrylic resin or the like may be applied in the display region 110A and the peripheral region 110B on the sealing substrate 21 provided with the auxiliary wiring 25. Subsequently, the applied acrylic resin may be formed into a desirable shape, using a photolithography process, to form the formed member 26A and the formed member 46A. Next, the conductive film 26B and the conductive film 46B made of ITO may be formed on the entire surface of the sealing substrate 21 including the formed member 26A and the formed member 46A by, for example, sputtering. As a result, the pillar 26 and the pillar 46 are formed. The conductive film 26B and the conductive film 46B may be integral with each other. The sealing panel 20 is completed by the above-described processes.

### [Process of Adhering Element Panel 10 and Sealing Panel 20]

Using a one-drop-fill (ODF) process as illustrated in FIGS. 9A to 9C, for example, the element panel 10 and the sealing panel 20 formed as described above may be adhered to each other. Specifically, an upper plate 41A and a lower plate 41B in a pair are prepared in a vacuum chamber, and then the sealing panel 20 is fixed to a surface, which faces the lower plate 41B, of the upper plate 41A, and the element panel 10 is fixed to a surface, which faces the upper plate 41A, of the lower plate 41B. Next, a peripheral edge portion of the element panel 10 on the lower plate 41B is surrounded by the sealant 39, and resin used to form the filling resin layer 19 is dropped in a region surrounded by the sealant 39 (FIG. 9A). Subsequently, the sealing panel 20 and the element panel 10 are adhered to each other in the vacuum chamber (FIG. 9B), and then a nitrogen (N₂) atmosphere is formed in the chamber to press the element panel 10 and the sealing panel 20 against each other. The resin is cured in this state, so that the filling resin layer 19 is allowed to be provided between the element panel 10 and the sealing panel 20 without a gap (FIG. 9C). The display unit 1 illustrated in FIG. 1 is completed by the above-described processes.

### [Operation of Display Unit 1]

In the display unit 1, when a driving current corresponding to an image signal of each color is applied to each of the organic light emitting elements 10R, 10G, 10B, and 10W, an electron and a positive hole are injected into the organic layer 16 through the first electrode 14 and the second electrode 18. The electron and the positive hole are recombined in the light emitting layer included in the organic layer 16, to cause emission of light. This light is extracted after passing through the second electrode 18, the color filter 23, and the sealing substrate 21. In this way, for example, an image of full color of R, G, B, and W may be displayed on the display unit 1. In addition, by application of an electric potential corresponding to the image signal to one end of the capacitor Cs in this image display operation, an electric charge corresponding to the image signal is stored in the capacitor Cs.

### [Functions and Effects of Display Unit 1]

In the display unit 1, the pillar 46 used to electrically connect the auxiliary wiring 25 and the wiring 32 is provided in the peripheral region 110B. Therefore, a surplus current after emission of light in each of the organic light emitting elements 10R, 10G, 10B, and 10W flows from the second electrode 18 of the organic light emitting elements 10R, 10G, 10B, and 10W, to the wiring 32 through the pillar 26, the auxiliary wiring 25, and the pillar 46.

If there is no pillar in a peripheral region, a current flows from an auxiliary wiring of a sealing panel to a wiring of an element panel, through a pillar provided in a peripheral edge in a display region, namely, a pillar electrically connected to an organic light emitting element. In this case, currents from all of the organic light emitting elements concentrate on the pillar in the peripheral edge of the display region. Therefore, resistance of this pillar becomes high, which makes it difficult to uniformly apply voltage to the entire surface in the display region, although the auxiliary wiring is provided. This may cause display failure in the organic light emitting element in the peripheral edge of the display region.

In contrast, in the display unit 1, the pillar 46, which is different from the pillar 26 connected to the organic light emitting element 10R, 10G, 10B, or 10W, is provided in the peripheral region 110B, so that a rise in resistance of the pillar 26 in the display region 110A is suppressed. Therefore, it is possible to uniformly apply voltage to all of the organic light emitting elements 10R, 10G, 10B, and 10W in the display region 110A, which makes it possible to prevent occurrence of display failure.

Further, the pillar 46 and the pillar 26 are formed by the same process, so that the height of the pillar 46 and the height of the pillar 26 are the same. Therefore, if the configuration of the peripheral region 110B except the pillar 46 is substantially the same as the configuration of the display region 110A, the distance between the element panel 10 and the sealing panel 20 is readily kept constant between the display region 110A and the peripheral region 110B. Specifically, the flattening layer 13, the first contact electrode 34, the insulating film 35, and the second contact electrode 38, which have the same thicknesses as those of the flattening layer 13, the first electrode 14, the partition 15, and the second electrode 18, respectively, are provided in the peripheral region 110B. As a result, the configuration of the peripheral region 110B is allowed to be made substantially the same as the configuration of the display region 110A. When the distance between the element panel 10 and the sealing panel 20 is kept constant between the display region 110A and the peripheral region 110B as described above, poor connection between the pillar 26 and the second electrode 18 and between the pillar 46 and the second contact electrode 38 is prevented. Therefore, it is possible to achieve high display quality and to improve yield. Moreover, the number of manufacturing processes is reduced, so that a reduction in manufacturing cost is allowed.

For example, it is conceivable to form a structure for connection between an auxiliary wiring of a sealing panel and a wiring of an element panel in a peripheral region, by using a material such as metallic paste. However, in this case, the number of manufacturing processes increases, leading to an increase in cost. In addition, impurities such as the metallic paste may adhere to an organic light emitting element, which may cause display failure and a reduction in yield.

Further, adjustment of the distance between the element panel 10 and the sealing panel 20 is made easy by using the pillar 26 and the pillar 46 that are elastic. Therefore, it is possible to prevent poor connection between the pillar 26 and the second electrode 18 of the organic light emitting elements 10R, 10G, 10B, and 10W, with reliability.

In addition, the pillar 46 is provided inside the sealant 39, and is surrounded by the filling resin layer 19 cured by pressure. Therefore, the filling resin layer 19 serves as an adhesion reinforcing material, which allows prevention of poor connection between the pillar 46 and the second contact electrode 38.

Moreover, the distribution density of the pillars 46 in the peripheral region 110B is higher than the distribution density of the pillars 26 in the display region 110A, so that the currents flowing from the entire display region 110A are dispersed. Therefore, it is possible to reduce contact resistance between the auxiliary wiring 25 and the second contact electrode 38.

As described above, in the display unit 1, the pillar 46 is provided in the peripheral region 110B. Therefore, it is possible to apply the voltage uniformly to all of the organic light emitting elements 10R, 10G, 10B, and 10W in the display region 110A, so that occurrence of display failure is allowed to be suppressed. Hence, it is possible to improve display quality even if the size is increased.

A modification of the above-described embodiment will be described below. In the following description, the same components as those of the above-described embodiment will be provided with the same reference numerals as those thereof, and will not be described as appropriate.

### [Modification]

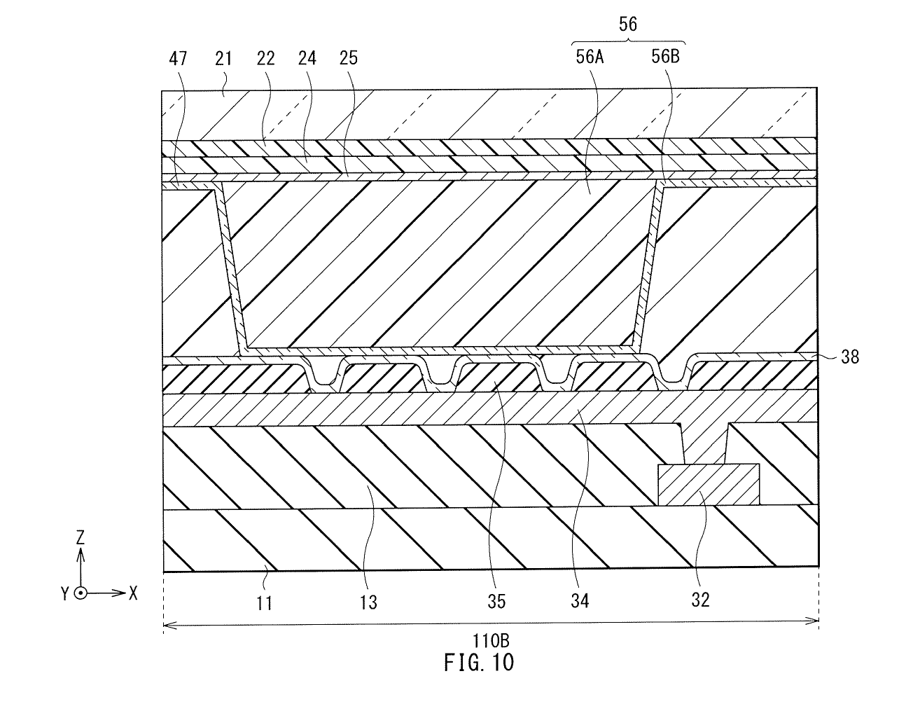

As illustrated in FIG. 10, a thickness of a pillar (a pillar 56) in the peripheral region 110B may be larger than the thickness of the pillar 26 (FIG. 1) in the display region 110A. In this case, the number of the connection holes 35H, in which the second contact electrode 38 and the first contact electrode 34 are in contact with each other, of the insulating film 35, may be two or more (FIG. 10), or may be one (not illustrated), for one pillar 56.

The pillar 56 includes a formed member 56A and a conductive film 56B, as with the pillar 46 (FIG. 1). The formed member 56A may have, for example, a thickness substantially five times larger than the thickness of the formed member 26A (FIG. 1) of the pillar 26 in the display region 110A. The formed member 56A may be preferably as thick as possible to the extent allowable in terms of design. When the pillar 46A in the peripheral region 110B is made thicker than the pillar 26 in the display region 110A, a contact area between the pillar 56 and the second contact electrode 38 increases, which allows a reduction in the contact resistance between the auxiliary wiring 25 and the second contact electrode 38.

### APPLICATION EXAMPLES

Examples of application of the display unit 1 as described above to electronic apparatuses will be described below. Examples of the electronic apparatuses may include television apparatuses, digital cameras, laptop personal computers, mobile terminal apparatuses such as mobile phones, and video cameras. In other words, the above-described display unit is applicable to electronic apparatuses in all fields that display externally-inputted image signals or internally-generated image signals as still or moving images.

### [Module]

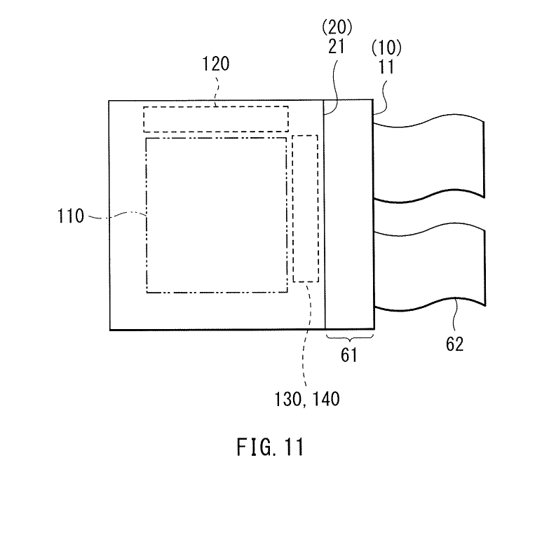

The above-described display unit 1 may be incorporated in various kinds of electronic apparatuses including Application examples 1 to 7 to be described below, as a module illustrated in FIG. 11, for example. In this module, for example, a region 61 exposed from the sealing substrate 21 or the element substrate 11 may be provided at one side of the element panel 10 or the sealing panel 20. In this exposed region 61, external connection terminals (such as a first peripheral electrode and a second peripheral electrode) are formed by extending wirings of the signal-line driving circuit 120, the scanning-line driving circuit 130, and the power-supply-line driving circuit 140. These external connection terminals may be provided with a flexible printed circuit (FPC) 62 for input and output of signals.

### Application Example 1

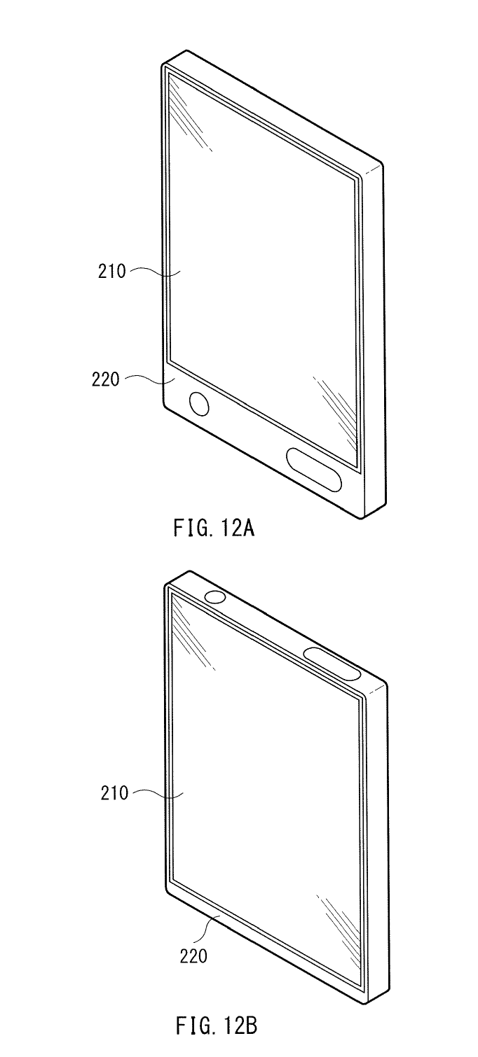

FIGS. 12A and 12B each illustrate an appearance of an electronic book to which the display unit 1 of the above-described embodiment is applied. This electronic book may include, for example, a display section 210 and a non-display section 220. The display section 210 is configured using the display unit 1 of the above-described embodiment.

### Application Example 2

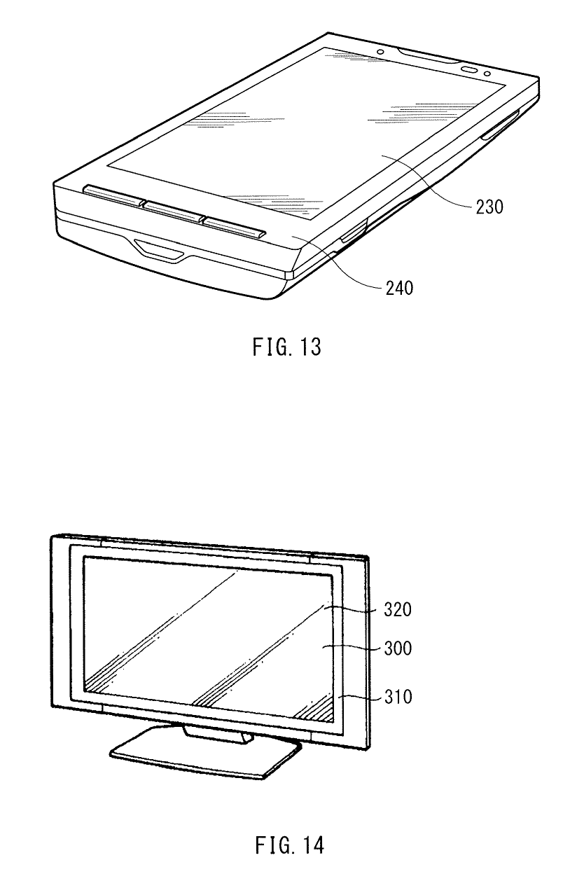

FIG. 13 illustrates an appearance of a smartphone to which the display unit 1 of the above-described embodiment is applied. This smartphone may include, for example, a display section 230 and a non-display section 240. The display section 230 is configured using the display unit 1 of the above-described embodiment.

### Application Example 3

FIG. 14 illustrates an appearance of a television apparatus to which the display unit 1 of the above-described embodiment is applied. This television apparatus may include, for example, an image-display screen section 300 including a front panel 310 and a filter glass 320. The image-display screen section 300 is configured using the display unit 1 of the above-described embodiment.

### Application Example 4

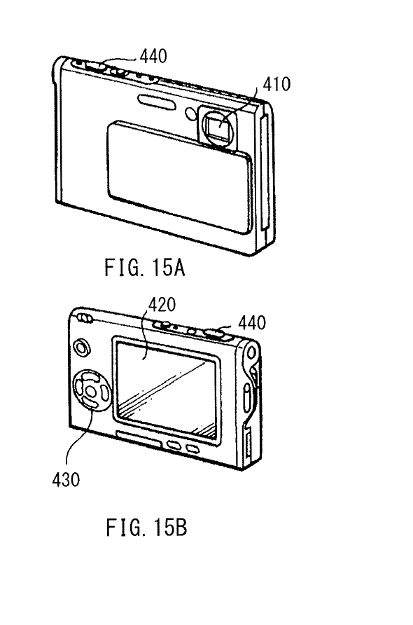

FIGS. 15A and 15B each illustrate an appearance of a digital camera to which the display unit 1 of the above-described embodiment is applied. This digital camera may include, for example, a flash emitting section 410, a display section 420, a menu switch 430, and a shutter button 440. The display section 420 is configured using the display unit 1 of the above-described embodiment.

### Application Example 5

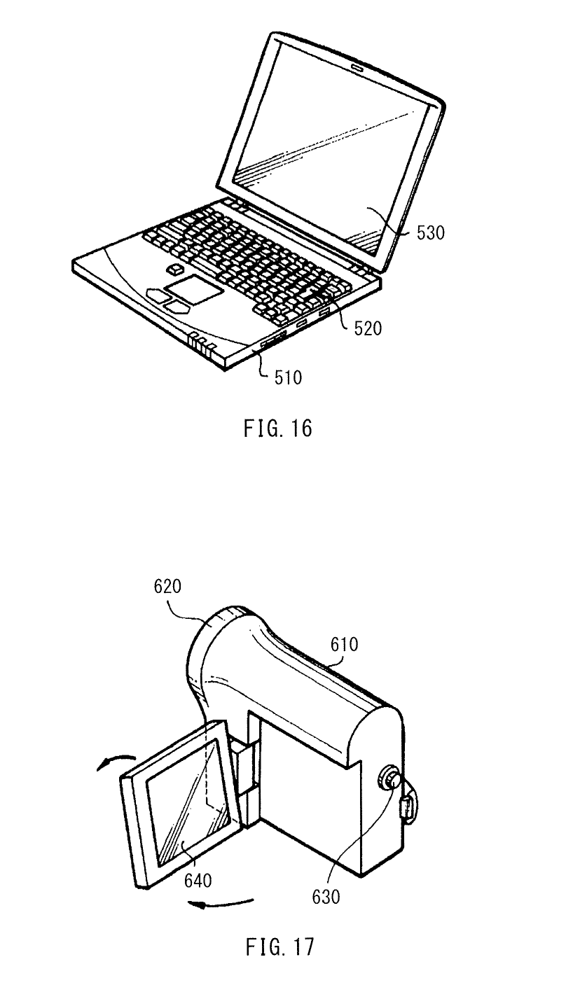

FIG. 16 illustrates an appearance of a laptop personal computer to which the display unit 1 of the above-described embodiment is applied. This laptop personal computer may include, for example, a main body section 510, a keyboard 520 provided to enter characters and the like, and a display section 530 displaying an image. The display section 530 is configured using the display unit 1 of the above-described embodiment.

### Application Example 6

FIG. 17 illustrates an appearance of a video camera to which the display unit 1 of the above-described embodiment is applied. This video camera may include, for example, a main body section 610, a lens 620 disposed on a front face of this main body section 610 to shoot an image of a subject, a start/stop switch 630 used in shooting, and a display section 640. The display section 640 is configured using the display unit 1 of the above-described embodiment.

### Application Example 7

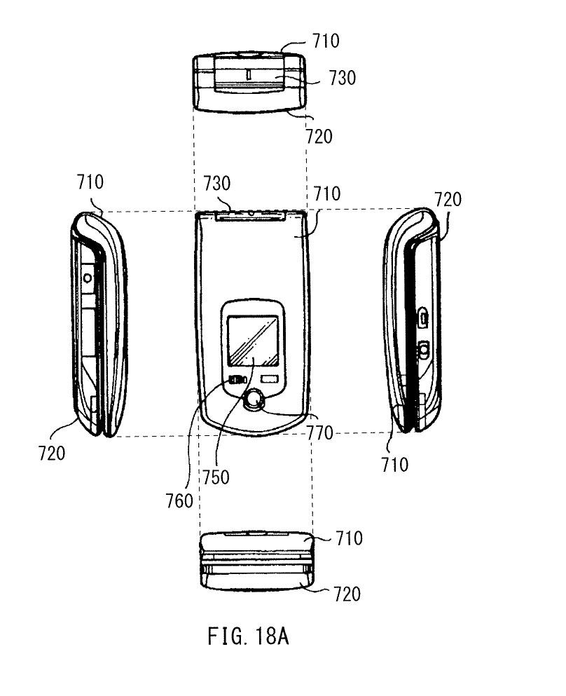

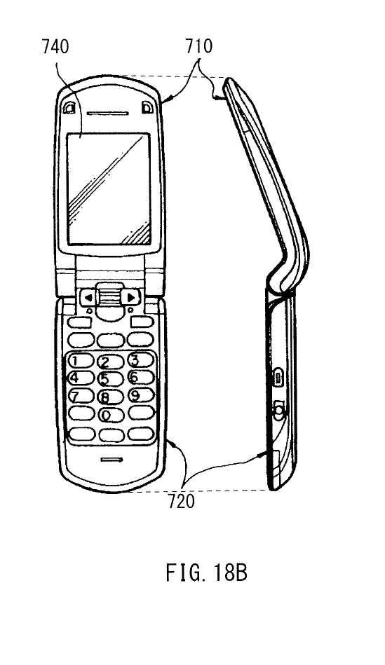

FIGS. 18A and 18B each illustrate appearances of a mobile phone to which the display unit 1 of the above-described embodiment is applied. This mobile phone may be, for example, a unit in which an upper housing 710 and a lower housing 720 are connected by a coupling section (a hinge section) 730, and may include a display 740, a sub-display 750, a picture light 760, and a camera 770. Of these components, the display 740 or the sub-display 750 is configured using the display unit 1 of the above-described embodiment.

The present technology has been described above with reference to some embodiment and modifications, but is not limited thereto and may be variously modified. For example, in the above-described embodiment and the like, the case in which all of the organic light emitting elements 10R, 10G, 10B, and 10W include the common organic layer 16 has been described as an example. However, it may be sufficient that any layer of the organic layer 16 is common to the organic light emitting elements 10R, 10G, 10B, and 10W. Alternatively, the organic layer 16 may be colored differently for each of the organic light emitting elements 10R, 10G, 10B, and 10W.

Further, in the above-described embodiment and the like, the case in which the red light emitting layer, the green light emitting layer, and the blue light emitting layer are laminated to generate white light. However, the configuration of the light emitting layers may be of any type. For example, a blue light emitting layer and a yellow light emitting layer may be laminated.

Furthermore, in the above-described embodiment and the like, the case in which the red, green, blue, and white sub-pixels are arranged by providing the red filter, the green filter, the blue filter, and the white filter as the color filter 23 has been described. However, a yellow sub-pixel may be provided in place of the white sub-pixel. Alternatively, the red, green, and blue sub-pixels may form one pixel.

Still furthermore, in the above-described embodiment and the like, the case of providing the high-resistive layer 17 has been described. However, one or both of the high-resistive layer and the overcoat layer may be omitted.

Moreover, in the above-described embodiment and the like, the case of electrically connecting the pillar 46 and the wiring 32 through the first contact electrode 34 and the second contact electrode 38 has been described. However, one or both of the first contact electrode and the second contact electrode may be omitted.

It is to be noted that the effects have been described herein only as examples without being limitative, and other effect may be provided.

It is possible to achieve at least the following configurations from the above-described example embodiments of the disclosure.

(1) A display unit including:

a plurality of light emitting elements provided in a display region of a first substrate, and including a first electrode, a light emitting layer, and a second electrode in this order on the first substrate;

an auxiliary wiring provided on a second substrate facing the first substrate with the light emitting elements interposed therebetween, and extending from the display region to a peripheral region surrounding the display region;

a first pillar configured to electrically connect the auxiliary wiring and the second electrode of the light emitting elements; and

a second pillar configured to electrically connect the auxiliary wiring and a peripheral electrode provided in the peripheral region of the first substrate.

(2) The display unit according to (1), wherein a height of the second pillar is equal to a height of the first pillar.
(3) The display unit according to (1) or (2), wherein the second electrode is provided to be common to the plurality of light emitting elements.
(4) The display unit according to (3), further including a partition between the light emitting elements next to each other,

wherein the first pillar is provided between the second electrode extending on the partition and the auxiliary wiring.

(5) The display unit according to (4), further including an insulating film provided in the peripheral region of the first substrate and having a thickness equal to a thickness of the partition.
(6) The display unit according to (5), wherein

the peripheral electrode includes,

a first contact electrode having a thickness equal to a thickness of the first electrode, and

a second contact electrode provided on the insulating film and having a thickness equal to a thickness of the second electrode, and

the second contact electrode is in contact with the first contact electrode in a connection hole provided in the insulating film.

(7) The display unit according to (6), wherein the first contact electrode is in contact with the second contact electrode in a plurality of connection holes of the insulating film.
(8) The display unit according to any one of (1) to (7), wherein the peripheral electrode is electrically connected to a common power supply line.
(9) The display unit according to any one of (1) to (8), wherein

the first pillar includes a plurality of first pillars, and the second pillar includes a plurality of second pillars, and

distribution density of the second pillars in the peripheral region is higher than distribution density of the first pillars in the display region.

(10) The display unit according to any one of (1) to (9), wherein a thickness of the second pillar is larger than a thickness of the first pillar.
(11) The display unit according to any one of (1) to (10), further including a filling resin layer provided around the second pillar.
(12) The display unit according to any one of (1) to (11), wherein the first pillar and the second pillar have elasticity.
(13) The display unit according to any one of (1) to (12), wherein the first pillar and the second pillar each include a formed member containing a resin material, and a conductive film covering the formed member.
(14) The display unit according to any one of (1) to (13), wherein the first pillar and the second pillar are configured of a same material.
(15) An electronic apparatus provided with a display unit, the display unit including:

a plurality of light emitting elements provided in a display region of a first substrate, and including a first electrode, a light emitting layer, and a second electrode in this order on the first substrate;

an auxiliary wiring provided on a second substrate facing the first substrate with the light emitting elements interposed therebetween, and extending from the display region to a peripheral region surrounding the display region;

a first pillar configured to electrically connect the auxiliary wiring and the second electrode of the light emitting elements; and

a second pillar configured to electrically connect the auxiliary wiring and a peripheral electrode provided in the peripheral region of the first substrate.

It should be understood by those skilled in the art that various modifications, combinations, sub-combinations, and alterations may occur depending on design requirements and other factors insofar as they are within the scope of the appended claims or the equivalents thereof.

What is claimed is:

1. A display unit comprising:
a plurality of light emitting elements provided in a display region of a first substrate, and including a first electrode, a light emitting layer, and a second electrode in this order on the first substrate;
an auxiliary wiring provided on a second substrate facing the first substrate with the light emitting elements interposed therebetween, and extending from the display region to a peripheral region surrounding the display region;
a first pillar configured to electrically connect the auxiliary wiring and the second electrode of the light emitting elements; and
a second pillar configured to electrically connect the auxiliary wiring and a peripheral electrode provided in the peripheral region of the first substrate.

2. The display unit according to claim 1, wherein a height of the second pillar is equal to a height of the first pillar.

3. The display unit according to claim 1, wherein the second electrode is provided to be common to the plurality of light emitting elements.

4. The display unit according to claim 3, further comprising a partition between the light emitting elements next to each other,
wherein the first pillar is provided between the second electrode extending on the partition and the auxiliary wiring.

5. The display unit according to claim 4, further comprising an insulating film provided in the peripheral region of the first substrate and having a thickness equal to a thickness of the partition.

6. The display unit according to claim 5, wherein
the peripheral electrode includes,
a first contact electrode having a thickness equal to a thickness of the first electrode, and
a second contact electrode provided on the insulating film and having a thickness equal to a thickness of the second electrode, and
the second contact electrode is in contact with the first contact electrode in a connection hole provided in the insulating film.

7. The display unit according to claim 6, wherein the first contact electrode is in contact with the second contact electrode in a plurality of connection holes of the insulating film.

8. The display unit according to claim 1, wherein the peripheral electrode is electrically connected to a common power supply line.

9. The display unit according to claim 1, wherein
the first pillar includes a plurality of first pillars, and the second pillar includes a plurality of second pillars, and
distribution density of the second pillars in the peripheral region is higher than distribution density of the first pillars in the display region.

10. The display unit according to claim 1, wherein a thickness of the second pillar is larger than a thickness of the first pillar.

11. The display unit according to claim 1, further comprising a filling resin layer provided around the second pillar.

12. The display unit according to claim 1, wherein the first pillar and the second pillar have elasticity.

13. The display unit according to claim 1, wherein the first pillar and the second pillar each include a formed member containing a resin material, and a conductive film covering the formed member.

14. The display unit according to claim 1, wherein the first pillar and the second pillar are configured of a same material.

15. An electronic apparatus provided with a display unit, the display unit comprising:
a plurality of light emitting elements provided in a display region of a first substrate, and including a first electrode, a light emitting layer, and a second electrode in this order on the first substrate;
an auxiliary wiring provided on a second substrate facing the first substrate with the light emitting elements interposed therebetween, and extending from the display region to a peripheral region surrounding the display region;
a first pillar configured to electrically connect the auxiliary wiring and the second electrode of the light emitting elements; and
a second pillar configured to electrically connect the auxiliary wiring and a peripheral electrode provided in the peripheral region of the first substrate.
